(19) United States
(12) Patent Application Publication
(10) Pub. No.: US 2026/0068560 A1
(43) Pub. Date: Mar. 5, 2026

(54) METHOD TO ENLARGE FEATURES IN SEMICONDUCTOR DEVICE LAYERS USING ION IMPLANTS OF DIFFERENT TEMPERATURES

(71) Applicant: Applied Materials, Inc., Santa Clara, CA (US)

(72) Inventors: Andrew Michael Waite, Beverly, MA (US); Nan Zheng, Malden, MA (US); Rajesh Prasad, Lexington, MA (US)

(73) Assignee: Applied Materials, Inc., Santa Clara, CA (US)

(21) Appl. No.: 18/816,772

(22) Filed: Aug. 27, 2024

(51) Int. Cl. H01L 21/3115; H01L 21/311

(52) U.S. Cl. CPC H01L 21/31155

(57) ABSTRACT

A method for modifying dimensions of features in semiconductor devices, including providing a semiconductor device layer stack including a photoresist layer disposed atop a silicon nitride layer, the photoresist layer having an opening formed therein, performing an ion etching process on the layer stack, wherein an ions pass through the opening in the photoresist layer and etch a corresponding opening in the silicon nitride layer, removing the photoresist layer from the silicon nitride layer, performing a first ion implantation process on the silicon nitride layer at a first temperature, performing a second ion implantation process on the silicon nitride layer at a second temperature lower than the first temperature, and performing a wet etch process on the silicon nitride layer, wherein a portion of the silicon nitride layer implanted by the second ion implantation process is preferentially removed from the silicon nitride layer.

### FIELD OF THE DISCLOSURE

Embodiments of the present disclosure relate to semiconductor processing techniques, and more particularly, to methods for enlarging features in semiconductor device layers in a highly precise manner during semiconductor device fabrication.

### BACKGROUND OF THE DISCLOSURE

Semiconductor device fabrication involves many discrete processes for creating desired features and properties in the material layers of a semiconductor device. Some of these processes include lithography, etching, deposition and ion implantation. Often, in the case of etching, a layer of material, sometimes referred to as a “mask layer” or a “hardmask layer,” is disposed on the surface of another layer of material, sometimes referred to as a “pattern layer,” to be etched. Portions of the hardmask layer are removed using an etching process (e.g., a reactive ion etching process), creating openings in the hardmask layer that expose portions of the underlying pattern layer. The exposed material of the pattern layer is then treated with another etching process to remove the exposed material and create a desired feature or pattern (e.g., a contact window or via) in the pattern layer.

As semiconductor devices continue to scale to smaller dimensions, the patterning of features within such devices becomes increasingly difficult due to the small size and dense packing of such features. For example, creating precisely dimensioned, nanometer scale openings in a hardmask layer using conventional etching processes is challenging, and modifying the dimensions of such openings after they have been etched in a hardmask layer is generally not feasible. Undesired variations in the dimensions of the openings are subsequently transferred to the features etched in the underlying pattern layer, which can detrimentally affect the performance of a completed semiconductor device.

A need exists for a convenient, cost-effective method of modifying the dimensions of openings in hardmask layers and other semiconductor device layers in a manner that does not significantly degrade throughput. With respect to these and other considerations the present improvements may be useful.

### SUMMARY

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

A method for modifying dimensions of features in semiconductor devices in accordance with an embodiment of the present disclosure may include providing a semiconductor device layer stack including a photoresist layer disposed atop a silicon nitride layer, the photoresist layer having an opening formed therein, performing an ion etching process on the layer stack, wherein an ions pass through the opening in the photoresist layer and etch a corresponding opening in the silicon nitride layer, removing the photoresist layer from the silicon nitride layer, performing a first ion implantation process on the silicon nitride layer at a first temperature, performing a second ion implantation process on the silicon nitride layer at a second temperature lower than the first temperature, and performing a wet etch process on the silicon nitride layer, wherein a portion of the silicon nitride layer implanted by the second ion implantation process is preferentially removed from the silicon nitride layer.

Another method for modifying dimensions of features in semiconductor devices in accordance with an embodiment of the present disclosure may include providing a semiconductor device layer stack including a photoresist layer disposed atop a silicon nitride layer, performing a photolithography process on the photoresist layer to form an opening in the photoresist layer, performing an ion etching process on the semiconductor device layer stack, wherein ions pass through the opening in the photoresist layer and etch a corresponding opening in the silicon nitride layer, removing the photoresist layer from the silicon nitride layer, performing a first ion implantation process on the silicon nitride layer at a first temperature in a range between 350 degrees Celsius and 700 degrees Celsius, performing a second ion implantation process on the silicon nitride layer at a second temperature in a range between 14 degrees Celsius and 24 degrees Celsius, wherein an ion beam implemented in the second ion implantation process is directed at a top surface of the silicon nitride layer at a non-zero angle relative thereto and strikes a side wall of the opening in the silicon nitride layer; and performing a wet etch process on the silicon nitride layer, wherein a portion of the silicon nitride layer implanted by the second ion implantation process is preferentially removed from the silicon nitride layer.

### BRIEF DESCRIPTION OF THE DRAWINGS

By way of example, various embodiments of the disclosed techniques will now be described with reference to the accompanying drawings, wherein:

FIGS. 1A-9B are a series of top views and corresponding cross-sectional views illustrating an exemplary process for modifying the dimensions of features formed in semiconductor device layers;

FIG. 10 is a flow diagram summarizing the processes shown in FIGS. 1A-9B.

### DETAILED DESCRIPTION

The present embodiments will now be described more fully hereinafter with reference to the accompanying drawings, wherein some exemplary embodiments are shown. The subject matter of the present disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

As used herein, an element or operation recited in the singular and proceeded with the word “a” or “an” are understood as possibly including plural elements or operations, except as otherwise indicated. Furthermore, various embodiments herein have been described in the context of one or more elements or components. An element or component may comprise any structure arranged to perform certain operations. Although an embodiment may be described with a limited number of elements in a certain topology by way of example, the embodiment may include more or less elements in alternate topologies as desired for a given implementation. Note any reference to “one embodiment” or “an embodiment” means a particular feature, structure, or characteristic described in connection with the embodiment is included in at least one embodiment. The appearances of the phrases “in one embodiment,” “in some embodiments,” and “in various embodiments” in various places in the specification are not necessarily all referring to the same embodiment.

The present embodiments provide novel techniques for selectively modifying the etch rates of materials during the fabrication of semiconductor devices (e.g., solar cells, vertical power field effect transistors, etc.), and particularly for modifying the etch rates of silicon nitride layers (e.g., hardmask layers) to achieve device features with desired dimensions. These techniques have been developed as a result of the inventors'discovery that the wet etch rate (WER) of silicon nitride layers in semiconductor devices can be precisely controlled by varying the temperature and order of ion implants performed on the silicon nitride layers.

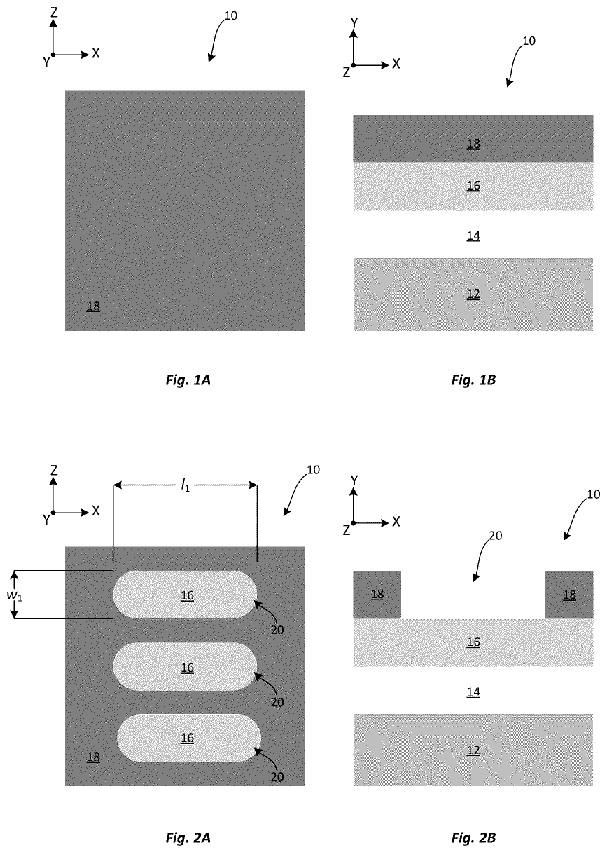

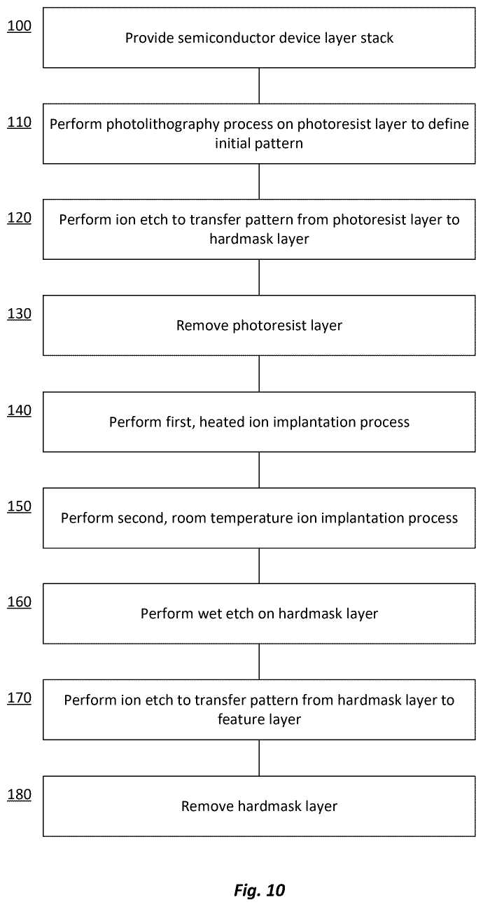

Referring to FIGS. 1A-9B, a series of top views and cross-sectional views illustrating an exemplary process for modifying the dimensions of openings formed in semiconductor device layers, and particularly semiconductor device layers formed of silicon nitride (e.g., hardmask layers), are shown. Referring to FIG. 10, a flow diagram summarizing the exemplary processes illustrated in FIGS. 1A-9B is provided. For the sake of convenience and clarity, terms such as “top,” “bottom,” “upper,” “lower,” “vertical,” “horizontal,” “lateral,” and “longitudinal,” may be used herein to describe the relative position and orientation of various structures and features, all with respect to the geometry and orientation of the structures and features as they appear in the views shown in FIGS. 1A-9B. Said terminology is not intended to be limiting and includes the words specifically mentioned, derivatives thereof, and words of similar import.

Referring to FIGS. 1A, 1B, and block 100 in FIG. 10, a semiconductor device layer stack 10 (hereinafter “the layer stack 10”) may be provided for facilitating a semiconductor device fabrication process. The layer stack 10 may include a substrate layer 12, a feature layer 14, a hardmask layer 16, and a photoresist layer 18 disposed in a vertically stacked arrangement in the aforementioned order. The substrate layer 12 may be formed of a semiconductor material including, and not limited to, silicon (e.g., crystalline silicon), germanium, silicon carbide, gallium arsenide, gallium nitride, etc. The feature layer 14 may be formed of a semiconductor material that is the same as, or different from, the semiconductor material of the substrate layer 12. The hardmask layer 16 may be formed of silicon nitride. The photoresist layer 18 may be formed of any conventional, light-sensitive organic material amenable to photolithography processes as will be familiar to those of ordinary skill in the art.

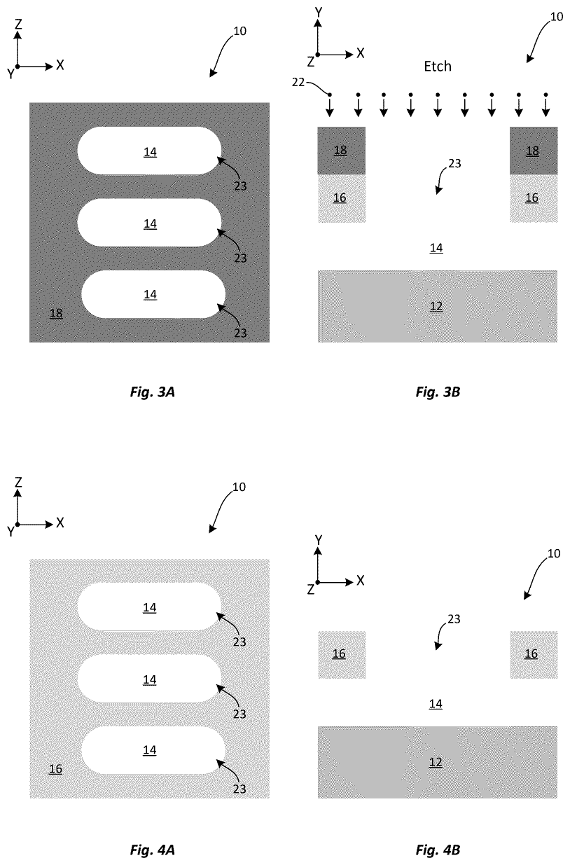

Referring to FIGS. 2A, 2B, and block 110 in FIG. 3, a photolithography process may be performed on the photoresist layer 18, wherein one or more portions of the photoresist layer 18 are removed (e.g., through ultraviolet light exposure and subsequent developing) to define a desired pattern in the photoresist layer 18 for subsequent transferal to the underlying layers of the layer stack 10 as further described below. For example, a plurality of slots or openings 20 (hereinafter “the openings 20”) may be formed in the photoresist layer 18, wherein the openings 20 correspond to trenches, vias, contact windows, or other semiconductor device features intended to ultimately be formed in the feature layer 14 of the layer stack 10 (via the hardmask layer 16) as further described below. The present disclosure is not limited in this regard. The openings 20 may have a first length l₁ measured along the X-axis of the illustrated Cartesian coordinate system and may have a first width w₁ measured along the Z-axis of the illustrated Cartesian coordinate system. Since conventional photolithography techniques are generally not capable of achieving device features with very small dimensions (e.g., nanometer scale dimensions) with high precision, the dimensions of the features formed in the photoresist layer 18 may be made smaller than the dimensions of such features intended to ultimately be formed in the feature layer 14. The features will then be expanded using the highly precise techniques of the present disclosure to achieve the desired, final feature dimensions as further described below.

Referring to FIGS. 3A, 3B, and block 120 in FIG. 10, the layer stack 10 may be subjected to a reactive ion etching (RIE) process, wherein the pattern defined by the photoresist layer 18 may be transferred to the hardmask layer 16. For example, chemically reactive ions 22 may be generated by an adjacent ion source (not shown) and may be directed at a top surface of the layer stack 10. The ions 22 may pass through the openings 20 formed in the photoresist layer 18 and may preferentially remove (i.e., etch) the exposed material of the hardmask layer 16, thus forming corresponding openings 23 in the hardmask layer 16 and exposing the underlying feature layer 14.

Referring to FIGS. 4A, 4B, and block 130 in FIG. 10, the photoresist layer 18 may be removed from layer stack 10 to expose the top surface of the hardmask layer 16. In various embodiments, the photoresist layer 18 may be removed using various solvents, plasma ashing, wet chemicals, or other techniques familiar to those of ordinary skill in the art. The present disclosure is not limited in this regard.

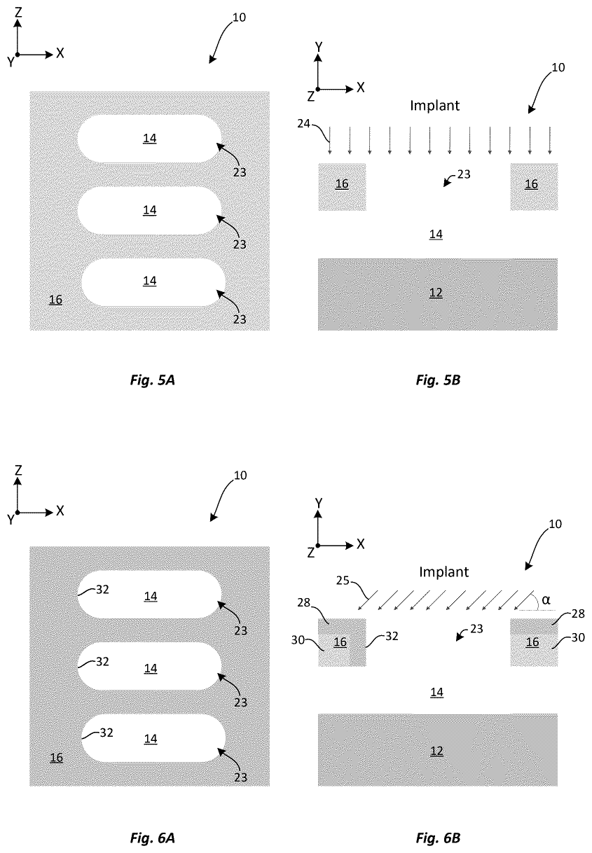

Referring to FIGS. 5A, 5B, and block 140 in FIG. 10, the layer stack 10 may be subjected to a first ion implantation process, wherein an ion beam 24 formed of an ionized dopant species is extracted from an adjacent ion beam source (not shown) and is directed at a top surface of the hardmask layer 16 at a perpendicular angle relative thereto. In various embodiments, the dopant species used for the first ion implantation process may be selected from fluorine, nitrogen, carbon, boron, silicon, germanium, argon, etc. The present disclosure is not limited in this regard. The first ion implantation process may be a “heated implant” performed at a temperature that is elevated relative to room temperature, where “room temperature” is defined herein as a temperature in a range between about 14 degrees Celsius and about 24 degrees Celsius. In various examples, the first ion implantation process may be performed at a temperature in a range of 350 degrees to 700 degrees Celsius. The present disclosure is not limited in this regard. Heating may be achieved using any known technique, including, and not limited to, backside heating via a heated platen (not shown) upon which the layer stack 10 may be disposed, ambient heating, etc. Furthermore, the first ion implantation process may be performed at an energy sufficient to implant most or all of the bulk of the hardmask layer 16. The first ion implantation process may serve to make the silicon nitride material of the hardmask layer 16 more resistant to a subsequent wet etching process as further described below.

Referring to FIGS. 6A, 6B, and block 150 in FIG. 10, the layer stack 10 may be subjected to a second ion implantation process, wherein an ion beam 25 formed of an ionized dopant species is extracted from an adjacent ion beam source (not shown) and is directed at a top surface of the hardmask layer 16 at a non-zero angle relative thereto. In various embodiments, the dopant species used for the second ion implantation process may be selected from fluorine, nitrogen, carbon, boron, silicon, germanium, argon, etc., and may be the same as or different than the dopant species used in the first ion implantation process. The second ion implantation process may be performed at room temperature and at an energy intended to effectuate only a shallow implant of the hardmask layer 16 (i.e., an implant to a depth that is less than the thickness of the hardmask layer 16 as measured along the Y-axis of the illustrated Cartesian coordinate system) to create a “removal portion” 28 within the hardmask layer 16. The removal portion 28 may be a portion of the hardmask layer 16 that is to be removed during a subsequent wet etching process as further described below.

The inventors have discovered through experimentation that by subjecting silicon nitride to a heated ion implantation process followed by a room temperature ion implantation process, the implanted material can be made significantly more susceptible to wet etching. Thus, the removal portion 28, having been subjected to both the first ion implantation process and the second ion implantation process described above, may be made significantly more susceptible to wet etching relative to the underlying portion of the hardmask layer 16, hereinafter referred to as “the survival portion” 30 of the hardmask layer 16, that was subjected to only the first ion implantation process.

The energy, direction, and non-zero angle a of the ion beam 25 implemented in the second ion implantation process may be selected based on the direction and degree to which features in the hardmask layer 16 are intended to be expanded. For example, as shown in FIG. 6A, if the openings 23 in the hardmask layer 16 are to be elongated along the X-axis of the illustrated Cartesian coordinate system, the ion beam 25 may be projected onto the hardmask layer 16 at an angle of approximately 45 degrees relative to a top surface thereof such that the ion beam 25 strikes the top surface of the hardmask layer 16 as well as the left-most longitudinal side walls 32 of the openings 23 in the hardmask layer 16 to form removal portion 28 therein. The direction and the non-zero angle a of the ion beam 25 may be adjusted by tilting and/or rotating the layer stack 10 (e.g., by tilting and/or rotating a platen upon which the layer stack 10 is disposed), and the depth of the removal portion 28 may be precisely controlled by varying the energy of the ion beam 25.

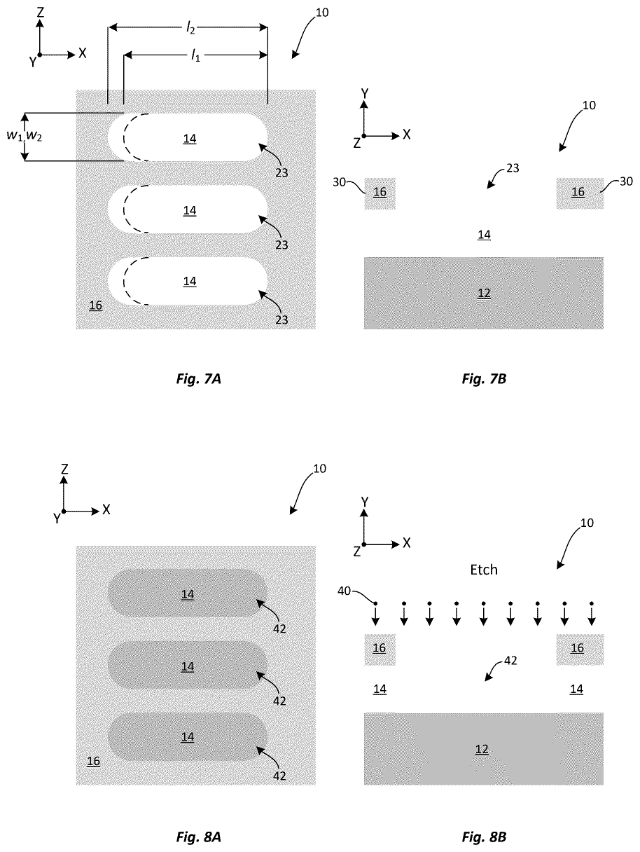

Referring to FIGS. 7A, 7B, and block 160 in FIG. 10, the hardmask layer 16 may be subjected to a wet etch process. For example, the hardmask layer 16 may be treated with an acid solution (e.g., a dilute hydrofluoric acid solution). As described above, the removal portion 28 of the hardmask layer 16 may be more susceptible to wet etching relative to the underlying survival portion 30 of the hardmask layer 16. Thus, the acid solution may preferentially remove the removal portion 28, including the left-most longitudinal side walls 32 of the openings 23, while leaving the survival portion 30 of the hardmask layer 16 entirely or mostly intact. The length of the openings 23 is thereby increased from the first length l₁, originally established via etching through the photoresist layer 18 as described above, to a second length l₂ equal to the length of slots intended to ultimately be formed in the feature layer 14 of the layer stack 10. Since the lateral side walls of the openings 23 were not exposed to the second ion implantation process and were therefore not significantly etched during the wet etch process, the openings 23 may have a second width w₂ substantially equal to the first width w₁.

Referring to FIGS. 8A, 8B, and block 170 in FIG. 10, the layer stack 10 may be subjected to a reactive ion etching (RIE) process, wherein the pattern defined by the hardmask layer 16, including the openings 23, may be transferred to the feature layer 14. For example, chemically reactive ions 40 may be generated by an adjacent ion source (not shown) and may be directed at a top surface of the layer stack 10. The ions 40 may pass through the openings 23 formed in the hardmask layer 16 and may preferentially remove (i.e., etch) the exposed material of the feature layer 14, thus forming corresponding slots 42 in the feature layer 14 and exposing the substrate layer 12. Particularly, the slots 42 may have the same (or nearly the same), precisely defined dimensions of the openings 23 in the hardmask layer 16, achieved using the sequential ion implantation processes described above.

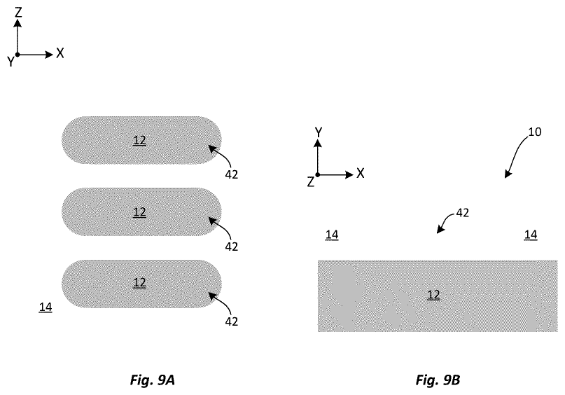

Referring to FIGS. 9A, 9B, and block 180 in FIG. 10, the hardmask layer 16 may be removed from layer stack 10 to entirely expose the feature layer 14. In various embodiments, the hardmask layer 16 may be removed using any appropriate chemical or physical etching processes know to those of skill in the art. The present disclosure is not limited in this regard.

In the example process described above and shown in FIGS. 1A-10, the sequential ion implantation processes of the present disclosure, including performing a heated ion implantation process followed by a room temperature ion implantation process, are performed on a silicon nitride hardmask layer to precisely define the dimensions of features therein. The present disclosure is not limited in this regard, and the described processes may similarly be performed on any layer or component formed of silicon nitride in a semiconductor device layer stack, including one or more of a feature layer, a substrate layer, etc.

Those of ordinary skill in the art will appreciate numerous advantages provided by the methods of the present disclosure. For example, the methods described herein facilitate the formation of features in silicon nitride layers of semiconductor devices with nanometer-scale precision. Furthermore, the methods of the present disclosure are cost-effective and can be implemented without significantly degrading workpiece throughput.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, while the present disclosure has been described herein in the context of a particular implementation in a particular environment for a particular purpose, those of ordinary skill in the art will recognize its usefulness is not limited thereto. Embodiments of the present disclosure may be beneficially implemented in any number of environments for any number of purposes. Accordingly, the claims set forth below shall be construed in view of the full breadth and spirit of the present disclosure as described herein.

1. A method for modifying dimensions of features in semiconductor devices, the method comprising:
providing a semiconductor device layer stack including a photoresist layer disposed atop a silicon nitride layer, the photoresist layer having an opening formed therein;
performing an ion etching process on the semiconductor device layer stack, wherein ions pass through the opening in the photoresist layer and etch a corresponding opening in the silicon nitride layer;
removing the photoresist layer from the silicon nitride layer;
performing a first ion implantation process on the silicon nitride layer at a first temperature;
performing a second ion implantation process on the silicon nitride layer at a second temperature lower than the first temperature; and
performing a wet etch process on the silicon nitride layer, wherein a portion of the silicon nitride layer implanted by the second ion implantation process is preferentially removed from the silicon nitride layer.

2. The method of claim 1, further comprising performing a photolithography process on the photoresist layer to form the opening in the photoresist layer.

3. The method of claim 1, wherein an ion beam implemented in the second ion implantation process is directed at a top surface of the silicon nitride layer at a non-zero angle relative thereto.

4. The method of claim 3, wherein the ion beam implemented in the second ion implantation process is directed at a side wall of the opening in the silicon nitride layer.

5. The method of claim 1, wherein the second ion implantation process is performed at an energy lower than the first ion implantation process.

6. The method of claim 1, wherein the first ion implantation process implants entirely through the silicon nitride layer and the second ion implantation process implants only partially through the silicon nitride layer.

7. The method of claim 1, wherein the first ion implantation process is performed at a temperature in a range between 350 degrees Celsius and 700 degrees Celsius.

8. The method of claim 1, wherein the second ion implantation process is performed at a temperature in a range between 14 degrees Celsius and 24 degrees Celsius.

9. The method of claim 1, wherein the ion etching process is a first ion etching process and wherein the silicon nitride layer is a hardmask layer, the method further comprising performing a second ion etching process on the semiconductor device layer stack, wherein ions pass through the opening in the silicon nitride layer and etch a corresponding opening in an underlying layer of the semiconductor device layer stack.

10. The method of claim 1, wherein a depth of the implant performed during the second ion implantation process is controlled by varying an energy of the second ion implantation process.

11. The method of claim 1, wherein a dopant species used in the first ion implantation process is one of fluorine, nitrogen, carbon, boron, silicon, germanium, and argon.

12. The method of claim 1, wherein a dopant species used in the second ion implantation process is one of fluorine, nitrogen, carbon, boron, silicon, germanium, and argon.

13. The method of claim 1, wherein the wet etch process enlarges the opening in the silicon nitride layer.

14. A method for modifying dimensions of features in semiconductor devices, the method comprising:
providing a semiconductor device layer stack including a photoresist layer disposed atop a silicon nitride layer;
performing a photolithography process on the photoresist layer to form an opening in the photoresist layer;
performing an ion etching process on the semiconductor device layer stack, wherein ions pass through the opening in the photoresist layer and etch a corresponding opening in the silicon nitride layer;
removing the photoresist layer from the silicon nitride layer;
performing a first ion implantation process on the silicon nitride layer at a first temperature in a range between 350 degrees Celsius and 700 degrees Celsius;
performing a second ion implantation process on the silicon nitride layer at a second temperature in a range between 14 degrees Celsius and 24 degrees Celsius, wherein an ion beam implemented in the second ion implantation process is directed at a top surface of the silicon nitride layer at a non-zero angle relative thereto and strikes a side wall of the opening in the silicon nitride layer; and
performing a wet etch process on the silicon nitride layer, wherein a portion of the silicon nitride layer implanted by the second ion implantation process is preferentially removed from the silicon nitride layer.

15. The method of claim 14, wherein the second ion implantation process is performed at an energy lower than the first ion implantation process.

16. The method of claim 14, wherein the first ion implantation process implants entirely through the silicon nitride layer and the second ion implantation process implants only partially through the silicon nitride layer.

17. The method of claim 14, wherein the ion etching process is a first ion etching process and wherein the silicon nitride layer is a hardmask layer, the method further comprising performing a second ion etching process on the semiconductor device layer stack, wherein ions pass through the opening in the silicon nitride layer and etch a corresponding opening in an underlying layer of the semiconductor device layer stack.

18. The method of claim 14, wherein a dopant species used in the first ion implantation process is one of fluorine, nitrogen, carbon, boron, silicon, germanium, and argon.

19. The method of claim 14, wherein a dopant species used in the second ion implantation process is one of fluorine, nitrogen, carbon, boron, silicon, germanium, and argon.

20. The method of claim 14, wherein the wet etch process enlarges the opening in the silicon nitride layer.
